(19) United States
(12) Patent Application Publication
(10) Pub. No.: US 2026/0296875 A1
(43) Pub. Date: Oct. 1, 2026

(54) ADJUSTABLE MILLIMETER WAVE RF MEMS SWITCH

(71) Applicant: QuantumZ Inc., Kaohsiung City (TW)

(72) Inventors: He-Tsung HUNG, Kaohsiung City (TW); Meng-Hua TSAI, Kaohsiung City (TW); Sin-Siang WANG, Kaohsiung City (TW); Wei-Ting LEE, Kaohsiung City (TW)

(21) Appl. No.: 19/221,454

(22) Filed: May 28, 2025

(30) Foreign Application Priority Data
Mar. 28, 2025 (TW) 114112160

(51) Int. Cl. B81B 3/00; H01H 59/00

(52) U.S. Cl. CPC B81B 3/0059; H01H 59/0009; B81B 2203/0109; B81B 2203/04

(57) ABSTRACT

The present disclosure relates to an adjustable millimeter wave radio frequency (RF) micro-electro-mechanical system (MEMS) switch, including a substrate, a signal line, a metal beam, capacitive coupling structures, and a short-circuited stub. The metal beam includes two fixed ends, two bending portion and an adsorption portion, and is connected to the substrate, drive electrode and signal line. The capacitive coupling structures are located between the bending portions of the metal beam and the drive electrodes, and provide an adsorption force required for switching actuation. The MEMS switch is combined with a liquid crystal polymer (LCP) substrate and applicable to the millimeter wave operating frequency. The disclosed RF MEMS switch surpasses mainstream 26 GHz in the market, and enables adjustable operating frequencies. This RF MEMS switch is featured with a low actuating voltage, small transmission loss, and applicable to flexible printed circuit board. Extensive application potential is anticipated.

### CROSS-REFERENCE TO RELATED APPLICATION

This application claims the benefit of Taiwan Patent Application No. 114112160, filed on Mar. 28, 2025, which is hereby incorporated by reference for all purposes as if fully set forth herein.

### BACKGROUND

### Technical Field

The present invention relates to the field of radio frequency (RF) technologies, and specifically, to an adjustable millimeter wave RF micro-electro-mechanical system (MEMS) switch.

### Related Art

A beamforming technology is often utilized to improve the transmission distance in an RF product. A large number of switches are required for signal switching in a beamforming array antenna. MEMS switches use micro-mechanics and electrostatics to control signal on and offs, and have been well received because of their high isolation and low insertion loss. Compared to conventional mechanical switches, MEMS switches provide faster responses, smaller sizes, and lower power consumptions.

A bridge structure is common in implementing a MEMS switch, where a movable electrode is pulled to a fixed electrode by an electrostatic attraction force until a “pull-in voltage” is reached. For example, Chinese Patent Application No. 201610150763.3 discloses a miniature capacitive RF switch which effectively reduces the overall size of a MEMS switch.

However, existing RF MEMS switches are prone to signal blocking when the operating frequency reaches a millimeter wave frequency band (typically above 24 GHz). This phenomenon makes such switch architecture incapable in 28 GHz or higher. Therefore, the operating frequency of mainstream RF MEMS switches in the market is up to 26 GHz.

### SUMMARY

To overcome the foregoing limits, the present invention provides an adjustable millimeter wave RF MEMS switch including a substrate with at least one signal line and a metal beam disposed across the signal line. A first fixed end and a second fixed end are respectively located on two sides of the signal line, and a first bending portion and a second bending portion are respectively connected to the first fixed end and the second fixed end. An adsorption portion is disposed between the first bending portion and the second bending portion.

A first drive electrode and a second drive electrode are respectively located on two sides of the signal line, where the first fixed end and the second fixed end are separately connected to the substrate. Projection areas of the first bending portion and the second bending portion at least partially overlap the first drive electrode and the second drive electrode respectively. A projection area of the adsorption portion at least partially overlaps the signal line.

Two capacitive coupling structures are respectively located between the first bending portion of the metal beam and the first drive electrode, and between the second bending portion of the metal beam and the second drive electrode to implement capacitive coupling.

A short-circuited stub is disposed on the substrate on the side of the second fixed end and connected to the second fixed end.

Optionally, an open-circuited stub is disposed on the substrate on the side of the first fixed end and connected to the first fixed end.

When the first drive electrode and the second drive electrode receive a drive voltage, the first bending portion and the second bending portion are attracted towards the first drive electrode and the second drive electrode due to the electrostatic attraction force. The adsorption portion is hence moved to be in contact with the signal line, and the RF signal in the signal line is directed to the ground via the short-circuited stub and hence blocked by the shorted-circuited stub. On the contrary, the RF signal in the signal line is not blocked when the first drive electrode and the second drive electrode do not receive a drive voltage, and the first bending portion and the second bending portion are not driven by an electrostatic attraction force to move the adsorption portion to be in contact with the signal line. The shorted-circuited stub and open-circuited stub correspond to the operation frequency and may be adjusted to adapt to different frequencies and bandwidths, especially in millimetre wave.

In some embodiments, slots are carved in the adsorption portion and the bending portions of the metal beam. These slots are not only designed to enhance the structural stability of the metal beam, but also to aid the metal beam to withstand stress from all directions, and thereby improve the overall elasticity and durability of the metal beam.

In some embodiments, the adjustable millimeter wave RF MEMS switch further includes a first insulation layer between the first bending portion of the metal beam and the first drive electrode and in contact with the first drive electrode. A second insulation layer between the second bending portion of the metal beam and the second drive electrode and in contact with the second drive electrode.

The adjustable millimeter wave RF MEMS switch of the present invention fulfils many RF application scenarios and may be utilized in various communication devices, radar, and satellite communications systems. The high reliability and performance features of the millimeter wave RF MEMS switches provide stable and reliable RF signal switching operations in communication systems required in complex environments such as satellite ground station, aviation communication equipment, and vehicle environment detecting devices.

### BRIEF DESCRIPTION OF THE DRAWINGS

FIG. 1 is a schematic diagram illustrating a structure of an adjustable millimeter wave RF MEMS switch according to the present invention.

FIG. 2 is a schematic cross-sectional view of the adjustable millimeter wave RF MEMS switch according to the present invention.

FIG. 3 is a schematic diagram illustrating a structure of an embodiment of the adjustable millimeter wave RF MEMS switch according to the present invention.

FIG. 4 is a schematic diagram illustrating a structure of another embodiment of the adjustable millimeter wave RF MEMS switch according to the present invention.

FIG. 5 is a top view of FIG. 4.

### DETAILED DESCRIPTION

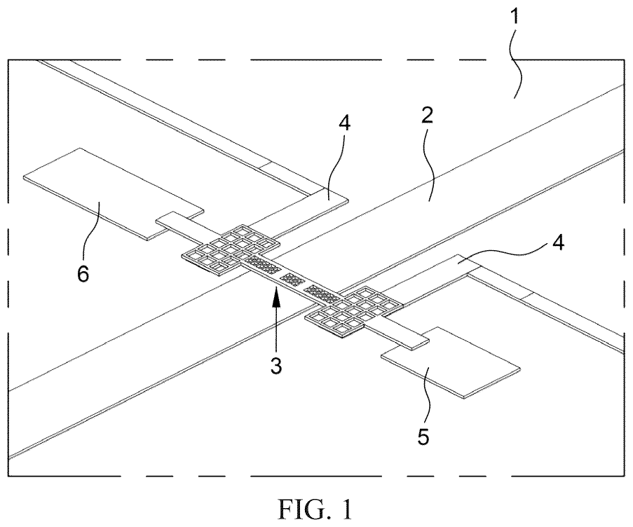

Referring to FIG. 1, a schematic diagram illustrating a structure of the adjustable millimeter wave radio frequency (RF) micro-electro-mechanical system (MEMS) switch according to the present invention. This RF MEMS switch includes a substrate 1, a signal line 2, a metal beam 3, drive electrodes 4, an open-circuited stub 5 and a short-circuited stub 6. The metal beam 3 is disposed across the signal line 2 and the drive electrodes 4.

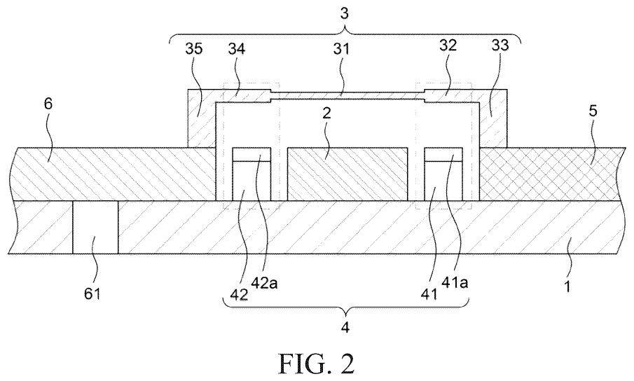

Referring to FIG. 2, a schematic cross-sectional view of the adjustable millimeter wave RF MEMS switch according to the present invention. The metal beam 3 includes a first fixed end 33 and a second fixed end 35 respectively located on two sides of the signal line 2. A first bending portion 32 is connected to the first fixed end 33, and a second bending portion 34 is connected to the second fixed end 35. An adsorption portion 31 is disposed between the first bending portion 32 and the second bending portion 34.

The drive electrodes 4 include a first drive electrode 41 and a second drive electrode 42. The first drive electrode 41 and the second drive electrode 42 are respectively located on the two sides of the signal line 2.

Projection areas of the first bending portion 32 and the second bending portion 34 at least partially overlap the first drive electrode 41 and the second drive electrode 42 respectively. A projection area of the adsorption portion 31 at least partially overlaps the signal line 2.

Two capacitive coupling structures (shown by dashed-line boxes in FIG. 2) are respectively formed between the first bending portion 32 and the first drive electrode 41, and between the second bending portion 34 and the second drive electrode 42 of the metal beam 3, to implement capacitive coupling.

The open-circuited stub 5 is disposed on the substrate 1 on the side of the first fixed end 33 and connected to the first fixed end 33.

The short-circuited stub 6 is disposed on the substrate 1 on the side of the second fixed end 35 and connected to the second fixed end 35. The short-circuited stub 6 is grounded through a through-hole 61 to form a reference ground, so as to provide a voltage difference required for activating the metal beam 3.

When the first drive electrode 41 and the second drive electrode 42 receive a drive voltage, the first bending portion 32 and the second bending portion 34 are attracted towards the first drive electrode 41 and the second drive electrode 42 due to an electrostatic attraction force. The adsorption portion 31 is pulled to be in contact with the signal line 2, the RF signal in the signal line 2 flows into ground via the short-circuited stub 6 and is hence blocked. On the contrary, the RF signal in the signal line 2 is not blocked when the first drive electrode 41 and the second drive electrode 42 do not receive the drive voltage, the first bending portion 32 and the second bending portion 34 are not affected by an electrostatic attraction force and thus the adsorption portion 31 is not in contact with the signal line 2. In this way, the MEMS switch controls signal on and offs.

The capacitive coupling structures between the bending portions 32, 34 of the metal beam 3 and the drive electrode 41, 42 further include one or more insulation layers 41a, 42a, to prevent direct contact between the metal beam 3 and the drive electrode 41, 42, thereby avoiding a short circuit or even breakage of the metal beam 3.

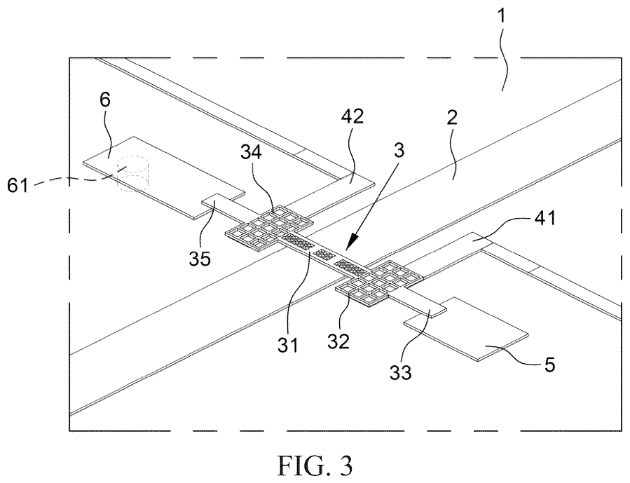

Referring to FIG. 3, a schematic diagram illustrating a structure of an embodiment of the adjustable millimeter wave RF MEMS switch according to the present invention. In this embodiment, material of the metal beam 3 may be gold, copper, or aluminium. The adsorption portion 31 may optionally surface treated, for example, partially plated with gold (Au), platinum (Pt), silver (Ag), palladium (Pb), nickel (Ni), or an alloy containing above metals. Such surface treatment is to improve contact reliability between the adsorption portion 31 and the signal line 2.

In some embodiments, the length of the open-circuited stub 5 is a quarter of the guided wavelength, and the length of the short-circuited stub 6 is half of the guided wavelength. The guided wavelength is the wavelength of the centre frequency in the substrate 1. The short-circuited stub 6 and the second drive electrode 42 are jointly grounded. The open-circuited stub 5 and the short-circuited stub 6 correspond to the same frequency. However, the open-circuited stub 5 and the short-circuited stub 6 do not necessarily correspond to the same frequency. A better filtering may be achieved when corresponding to the same frequency, and a wilder bandwidth may be achieved when corresponding frequencies are staggered. Furthermore, the length of the open-circuited stub 5 and the length of the short-circuited stub 6 are also determined by their widths and the dielectric value of the substrate of choice. The width of a stub affects transmission characteristics such as characteristic impedance and quality factor. The dielectric value of the selected substrate may shorten the length of the actual guided wave in substrate than in air. Therefore, lengths of the open-circuited stub 5 and the short-circuited stub 6 need to be adjusted accordingly to achieve optimal performance.

The metal beam 3 has to be strong but flexible. In practice, a plurality of slots may be carved in the bending portion 32, 34. These slots not only improve the structural stability of the metal beam 3, but also enable the metal beam 3 to more effectively withstand stress from different directions while being bent, thereby enhancing the overall elasticity and durability. Shapes and locations of the slots may be optimized according to the material, structure, and application scenario of the metal beam 3, and hence to balance factors such as structural stiffness, sensitivity, stress distribution, and manufacturing capabilities. Details are not discussed herein.

In some embodiments, insulation layers 41a, 42a, are disposed between the bending portions 32, 34 of the metal beam 3 and the drive electrodes 41, 42 and in contact with the drive electrode 41, 42. In this embodiment, the insulation layers 41a, 42a are made of silicon dioxide dielectric. However, other insulation materials such as silicon nitride and polyimide may also be used in present invention and not limited thereto.

In some embodiments, the material of the metal beam 3 is gold, copper, or aluminium. The surface of the metal beam 3 is surface treated, especially at the adsorption portion 31, such as plated with gold (Au), platinum (Pt), silver (Ag), palladium (Pb), nickel (Ni), or an alloy of the above metals, to improve contact reliability between the adsorption portion 31 and the signal line 2.

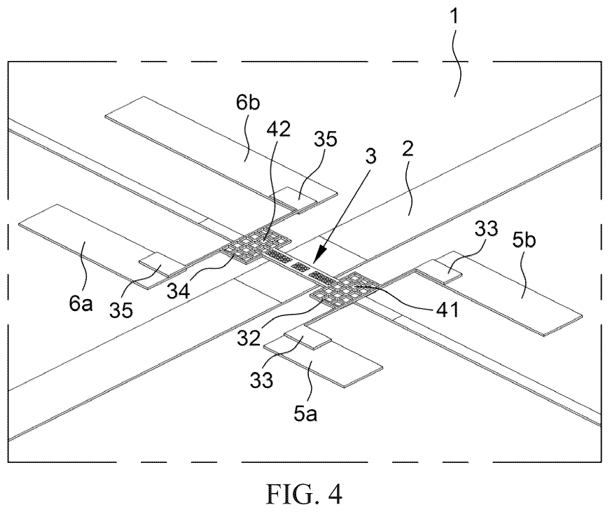

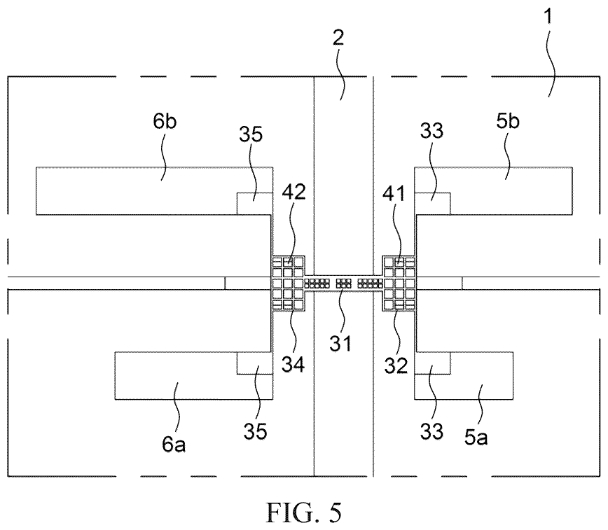

Referring to FIG. 4 and FIG. 5, another embodiment of the adjustable millimeter wave RF MEMS switch according to the present invention. As shown in FIG. 4 and FIG. 5, a first open-circuited stub 5a and a first short-circuited stub 6a correspond to the same operating frequency band. A second open-circuited stub 5b and a second short-circuited stub 6b correspond to another operating frequency band. The length of the first open-circuited stub 5a is different from that of the second short-circuited stub 5b, and the length of the first short-circuited stub 6a is different from that of the second short-circuited stub 6b. Such design enables the adjustable millimeter wave RF MEMS switch to operate in two different frequency bands.

In some embodiments, the adjustable millimeter wave RF MEMS switch operate in both 25 GHz and 50 GHz. The wavelength of 25 GHz is 12 mm, and the wavelength of 50 GHz is 6 mm. Therefore, the length of the first open-circuited stub 5 a may be 3 mm (¼ of 12 mm), the length of the first short-circuited stub 6 a may be 6 mm (½ of 12 mm), the length of the second open-circuited stub 5 b may be 1.5 mm (¼ of 6 mm), and the length of the second short-circuited stub 6 b may be 3 mm (¼ of 6 mm). In this way, the millimeter wave RF MEMS switch is adjusted to control signal switches in both frequency bands, namely, 25 GHz and 50 GHz.

The wavelength is also affected by different materials of the substrate 1 with different dielectric constants. In some embodiment, the substrate 1 of the millimeter wave RF MEMS switch includes LCP material with an effective dielectric constant of 3. Therefore, the guided wavelength at 50 GHz is 6 mm/√3=3.464 mm, while the guided wavelength at 25 GHz is 12 mm/√3=6.928 mm. The lengths of the first open-circuited stub 5 a, the second open-circuited stub 5b, the first short-circuited stub 6a, and the second short-circuited stub 6b all need to be adjusted accordingly. The LCP substrate is selected for this embodiment, but the present invention is not limited thereto, and may also include other suitable substrate alternatives.

In some embodiments, the length of the first open-circuited stub 5a is the same as the length of the second short-circuited stub 5b, and the length of the first short-circuited stub 6a is the same as the length of the second short-circuited stub 6b. When the two groups of stubs correspond to a same frequency, the millimeter wave RF MEMS switch may achieve a better filtering performance.

In some embodiments, the two groups of stubs correspond to two different but similar frequencies may broaden the bandwidth. The frequency corresponding to the first open-circuited stub 5a and the first short-circuited stub 6a is slightly staggered from the frequency corresponding to the second short-circuited stub 5b and the second short-circuited stub 6b can increase the bandwidth.

In some embodiments, there may be more than two groups of stubs. The number of groups of stubs and the lengths of the first open-circuited stub 5a, the second open-circuited stub 5b, the first short-circuited stub 6a, and the second short-circuited stub 6b may be varied according to different purposes. By adjusting the lengths, widths, and number of groups of the stubs, the millimeter wave RF MEMS switch of the present invention can also adapt to substrates of different dielectric materials to improve the product design variables.

In some embodiments, the adjustable millimeter wave RF MEMS switch further includes a packaging layer (not shown by figure). The design of the packaging layer is not only to protect and fix the substrate 1, the metal beam 3, and the capacitive coupling structures, but also to integrate and optimize these key components. Through a carefully designed packaging structure, these components are closely connected internally to form a highly integrated system. The packaging layer not only provides physical protection to prevent interference and damage from an external environment to internal components, but also controls an internal temperature to ensure components operate in an optimally. In addition, the packaging layer further optimizes connections and layouts to improve performance and reliability of the entire system.

Further, the packaging layer may be made of ceramic, metal, or polymer. These materials may be used individually or in combination to satisfy different application requirements. Polymers are widely used in electronic packaging for its lightweight, low in costs, and easy to manufacture. Ceramics are typically used for packaging of high-performance electronic devices due to their excellent insulation and high-temperature resistance. Metals are often used in application scenarios needing heat radiation and impact resistance. Diversified functions of the packaging layer can be implemented by selecting suitable materials or combinations.

The adjustable millimeter wave RF MEMS switch according to the present invention fulfils many RF application scenarios and can be widely used in various communication devices, radar systems, and satellite communication fields. Featured by high reliability and performance, the adjustable millimeter wave RF MEMS switch can provide stable and reliable RF signal switching to ensure smooth operation in various complex environments such as a satellite ground station, aviation communication equipment, and vehicle environment detecting devices.

The manufacturing process of the adjustable millimeter wave RF MEMS switch according to the present invention involves a variety of microelectronic manufacturing such as photolithographing, etching, plating. The photolithographing is used for precisely forming a desired pattern on a substrate, and etching is used for removing excess material to form a specific structure. The plating involves depositing one or more layers of thin film materials onto designated surfaces to achieve desired electrical and mechanical properties. Finally, the microelectronics manufacturing technology integrates these steps to ensure high performance and reliability of the RF MEMS switch.

In conclusion, the millimeter wave RF MEMS switch of the present invention combined with the LCP substrate may achieve an operating frequency of 50 GHz and higher. This performance significantly exceeds the limitation of 26 GHz achieved by most products in the market. The operating frequency range in higher millimeter wave is made possible.

In addition, the adjustable millimetre wave RF MEMS switch of the present invention requires a relatively low adsorption voltage at actuation. This RF MEMS switch is applicable to flexible printed circuit boards and have a relatively small overall transmission loss. Extensive potential for application in millimeter wave communication is anticipated.

The foregoing embodiments are merely intended to describe and not to limit the technical solutions of the present invention. Although the present invention has been described in detail with reference to the foregoing embodiments, a person of ordinary skill in the art should understand and make modifications to the technical solutions described in the foregoing embodiments or make equivalent replacements to some of the technical features thereof. These modifications or replacements do not make the essence of the corresponding technical solutions deviate from the spirit and scope of the technical solutions of the embodiments of the present invention.

What is claimed is:

1. An adjustable millimeter wave radio frequency (RF) micro-electro-mechanical system (MEMS) switch, comprising:
a substrate comprising at least one signal line;
a metal beam disposed across the signal line and comprising a first fixed end and a second fixed end respectively located on two sides of the signal line, a first bending portion and a second bending portion respectively connected to the first fixed end and the second fixed end, and an adsorption portion disposed between the first bending portion and the second bending portion;
a first drive electrode and a second drive electrode respectively located on the two sides of the signal line, wherein the first fixed end and the second fixed end are separately connected to the substrate, projection areas of the first bending portion and the second bending portion respectively at least partially overlap the first drive electrode and the second drive electrode, and a projection area of the adsorption portion at least partially overlaps the signal line;
two capacitive coupling structures respectively located between the first bending portion of the metal beam and the first drive electrode and between the second bending portion of the metal beam and the second drive electrode to implement capacitive coupling driving; and
a short-circuited stub disposed on the substrate on a side of the second fixed end and connected to the second fixed end.

2. The adjustable millimeter wave RF MEMS switch according to claim 1, further comprising an open-circuited stub disposed on the substrate on a side of the first fixed end and connected to the first fixed end, wherein a length of the open-circuited stub is approximately a quarter of a length of a guided wave of a center frequency.

3. The adjustable millimeter wave RF MEMS switch according to claim 1, wherein a length of the short-circuited stub is approximately a half of a length of a guided wave of a center frequency, and the short-circuited stub, the drive electrode, and the substrate are jointly grounded.

4. The adjustable millimeter wave RF MEMS switch according to claim 1, wherein a plurality of slots is provided in the bending portion and the adsorption portion.

5. The adjustable millimeter wave RF MEMS switch according to claim 4, wherein a surface of the adsorption portion of the metal beam is at least partially treated with a metal layer of gold (Au), platinum (Pt), silver (Ag), palladium (Pb), nickel (Ni), or an alloy consisting of the above metals.

6. The adjustable millimeter wave RF MEMS switch according to claim 2, wherein the open-circuited stub and the short-circuited stub correspond to a same frequency.

7. The adjustable millimeter wave RF MEMS switch according to claim 2, further comprising a plurality of short-circuited stubs and a corresponding plurality of open-circuited stubs.

8. The adjustable millimeter wave RF MEMS switch according to claim 7, wherein the plurality of short-circuited stubs and the corresponding plurality of open-circuited stubs respectively correspond to different operating frequency bands, enabling the adjustable millimeter wave RF MEMS switch to correspond to different operating frequency bands.

9. The adjustable millimeter wave RF MEMS switch according to claim 7, wherein the plurality of short-circuited stubs and the corresponding plurality of open-circuited stubs correspond to a same operating frequency band, enabling the adjustable millimeter wave RF MEMS switch to achieve a better filtering effect.

10. The adjustable millimeter wave RF MEMS switch according to claim 7, wherein frequencies corresponding to the plurality of short-circuited stubs and the corresponding plurality of open-circuited stubs are slightly staggered, enabling an operating bandwidth of the adjustable millimeter wave RF MEMS switch to be increased.
